(19) United States
(12) Patent Application Publication
(10) Pub. No.: US 2007/0069327 A1
(43) Pub. Date: Mar. 29, 2007

(54) Method for manufacturing an integrated semiconductor device

(75) Inventors: Stefan Tegen, Dresden (DE); Klaus Mummler, Dresden (DE); Peter Baars, Dresden (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/238,115

(22) Filed: Sep. 29, 2005

(51) Int. Cl. H01L 29/00; H01L 21/4763

(52) U.S. Cl. 257/503; 438/619; 257/632

(57) ABSTRACT

In a method for manufacturing an integrated semiconductor device with low capacitive coupling between a conductive member and a via, a semiconductor substrate with a surface is provided. The conductive member is formed on the surface of the substrate wherein the conductive member is provided for conducting a current in a direction parallel to the surface of the substrate. A sacrifice structure is produced. A via is formed for conducting a current in a direction vertical to the surface of the substrate. The sacrifice structure at least partially defines the shape and position of the via and separates the conductive member and the via. The sacrifice structure is removed thereby generating a void in place of the sacrifice structure.

### TECHNICAL FIELD OF THE INVENTION

The present invention relates to a method for manufacturing an integrated semiconductor device and to an integrated semiconductor device with low capacitive coupling between two proximate conductors.

### BACKGROUND OF THE INVENTION

Miniaturization of integrated semiconductor devices is a permanent issue with multifaceted challenges. The linear dimensions of the microscopic structures of an integrated semiconductor device have a strong influence on the capacitive coupling between conductors of the device. The smaller the distance between two proximate conductors is, the higher is their mutual electrostatic capacitance and the stronger is their capacitive coupling. Due to capacitive coupling, the wanted signal on a first conductor generates an unwanted signal on a second conductor proximate to the first conductor. This unwanted signal on the second conductor interferes with wanted signals on the second conductor. Being a kind of noise the unwanted signal reduces the signal-to-noise ratio. In the worst case the unwanted signal obstructs in communication, or exchange of data, via the second conductor.

### SUMMARY OF THE INVENTION

The present invention relates to a method for manufacturing an integrated semiconductor device and to an integrated semiconductor device with low capacitive coupling between two proximate conductors. Preferably, the integrated semiconductor device is a memory device and the conductors are a bit line and a via connecting a storage capacitor and a transistor of the memory device.

The present invention provides a method for manufacturing an integrated semiconductor device or integrated semiconductor memory device with low capacitive coupling between a conductive member and a via or between any other two proximate conductors. The present invention also provides an integrated semiconductor device with low capacitive coupling between two proximate conductors.

In one embodiment of the present invention, there is a method for manufacturing an integrated semiconductor memory device with low capacitive coupling between a conductive member and a via. In this regards, the method comprises providing a semiconductor substrate with a surface; forming the conductive member on the surface of the substrate, the conductive member being provided for conducting a current in a direction parallel to the surface of the substrate; producing a sacrifice structure; forming the via, the via being provided for conducting a current in a direction vertical to the surface of the substrate, wherein the sacrifice structure at least partially defines the shape and position of the via, and wherein the sacrifice structure separates the conductive member and the via; and removing the sacrifice structure, thereby generating a void in place of the sacrifice structure.

In another embodiment of the present invention, there is a method for manufacturing an integrated semiconductor device with low capacitive coupling between proximate conductors. In this regard, the method comprises providing a semiconductor substrate with a surface; producing a sacrifice structure on the surface; forming a first conductor, wherein the first conductor is separated from a second conductor by the sacrifice structure; and removing the sacrifice structure, thereby generating a void in place of the sacrifice structure.

In still another embodiment of the present invention, there is a method for manufacturing an integrated semiconductor device with low capacitive coupling between two proximate conductors. In this regard, the method comprises providing a semiconductor substrate with a first conductor and a second conductor on a surface of the substrate and a sacrifice structure between the first conductor and the second conductor; removing the sacrifice structure, thereby generating a void in place of the sacrifice structure.

In another embodiment, the present invention is an integrated semiconductor device with a semiconductor substrate with a surface; a first conductor on the surface of the substrate; a second conductor on the surface of the substrate; and a void between the first conductor and the second conductor, wherein the void is filled with gas.

In yet another embodiment, the present invention is an integrated semiconductor device with a semiconductor substrate with a surface; a first conductor on the surface of the substrate; a second conductor on the surface of the substrate; and an insulating structure between the first conductor and the second conductor, wherein the insulating structure is produced by the following steps: removing a sacrifice structure between the first conductor and the second conductor, thereby generating a void in place of the sacrifice structure wherein the shape of the sacrifice structure is essentially equal to the shape of the insulating structure; and filling the void with an insulating material, thereby forming the insulating structure.

For two conductors, the mutual electrostatic capacitance not only depends on their distance and their geometry but also on the dielectric constant or k factor of the material between the conductors. So called low k material between the conductors reduces their mutual capacitance and capacitive coupling. However, the chemical and mechanical properties of most low k materials are adverse to common semiconductor processing technologies. Once applied to a substrate, low k materials should be exposed to any further processing only with utmost caution.

Another embodiment of the present invention is based o providing or producing a sacrifice structure between two proximate conductors of an integrated semiconductor device. This sacrifice structure is made from a material which can be easily processed with common technologies. According to a preferred embodiment, a through hole is produced in the sacrifice structure defining the size, shape and position of a via conductor. The through hole is filled with an electrically conductive material forming the via conductor. In a similar way, any conductors of any shape may be produced with the aid of a sacrifice structure.

Later on, the sacrifice structure is removed thereby generating a void, or cavity, in place of the sacrifice structure. The void is either filled with low k material or with air or any other gas. In the latter case it is advantageous to coat the walls of the void with an electrically insulating film preventing an electrical break down. Further, it is advantageous to seal the void from the environment of the device thereby preventing the intrusion of any material into the void.

In any case the sacrifice structure is removed and possibly replaced by a low k material at a time when no further processing steps or merely processing steps compatible with the low k material are to be performed. In particular, it is preferred that no lateral structuring of the low k material is necessary.

The present invention provides an advantage that the sacrifice structure is easily processed and no constraints need to be considered or observed in the design of the processing of the integrated semiconductor device, but a low capacitive coupling between proximate conductors is provided. The present invention is particularly advantageous for integrated semiconductor memory devices with minimum distances between bit lines or between bit lines and via conductors vertically connecting a cell transistor, or selection transistor, with a storage capacitor. According to the present invention self-aligning techniques and minimum distances even far below the lithography resolution are combined with low capacitive coupling.

### BRIEF DESCRIPTION OF THE DRAWINGS

The present invention is described in more detail below with reference to the exemplary embodiments and drawings, in which:

FIGS. 1 to 9 show vertical cross sections of an integrated semiconductor device according to the present invention.

FIGS. 10 to 12 show vertical cross sections of another integrated semiconductor device according to the present invention.

FIGS. 13 to 21 show vertical cross sections of another integrated semiconductor device according to the present invention.

FIGS. 22 and 23 show vertical cross sections of another integrated semiconductor device according to the present invention.

FIGS. 24 to 26 vertical cross sections of another integrated semiconductor device according to the present invention.

FIG. 27 is a schematic flow chart of a method according to the present invention.

### DETAILED DESCRIPTION OF THE INVENTION

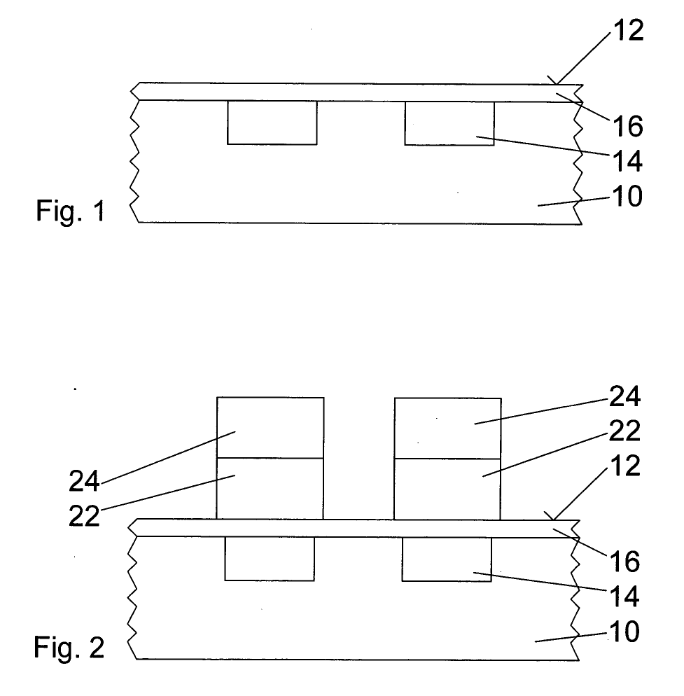

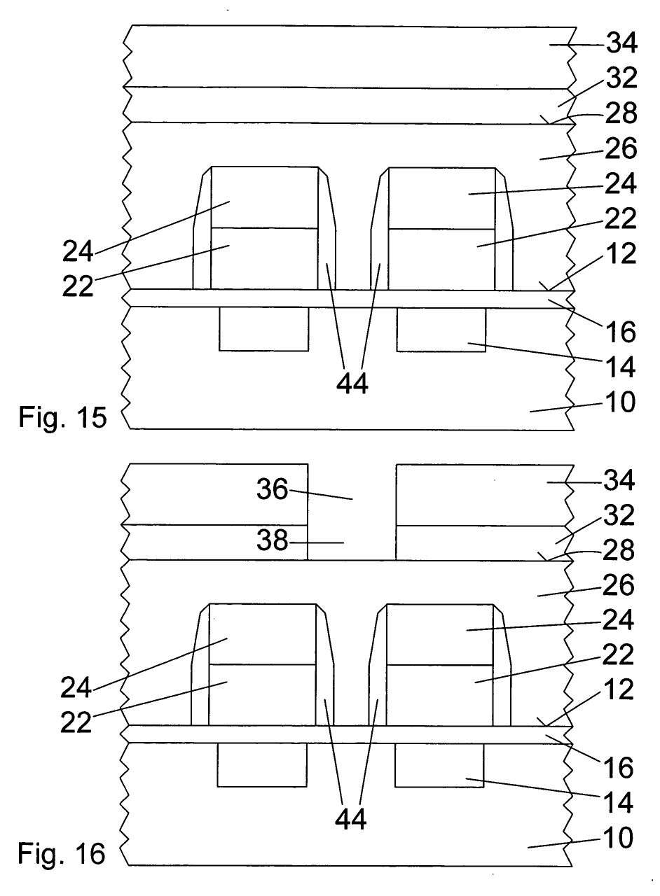

The FIGS. 1 to 26 display schematic views of cross sections of integrated semiconductor devices according to embodiments of the present invention. The cross section is always vertical, or perpendicular to a main surface of the substrate of the integrated semiconductor device. The Figures show different stages of the manufacturing process of the integrated semiconductor device.

The integrated semiconductor device is exemplified by an integrated semiconductor memory device. However, the present invention can be applied to any other kind of integrated semiconductor device as well. As already mentioned above, the present invention is particularly advantageous for highly miniaturized devices with a minimum distance between proximate conductors. In the example of the memory device, these proximate conductors with minimum distance are represented by a laterally elongated bit line and a vertically elongated via conductor vertically connecting a cell transistor, or selection transistor, in the semiconductor material of the substrate with a storage capacitor in or above the wiring layers of the device.

Referring to FIG. 1, a semiconductor substrate 10 with a surface 12 is provided. Preferably, the substrate 10 has already been processed. Field effect transistors, other transistors, diodes, resistors, capacitors and other electronic elements or at least part of them are formed within the substrate 10 and particularly below the surface 12 of the substrate 10. For a lateral electrical insulation, shallow trenches 14 filled with electrically insulating material are provided thereby forming a shallow trench insulation (STI) between laterally proximate elements within the substrate 10. A thin oxide layer 16 is formed at or below the surface 12 of the substrate 10.

It is emphasised that the structure of the substrate 10 displayed in FIG. 1 and the subsequent Figures as well as the particular geometry of the conductors and other structures subsequently produced on the substrate 10 are merely examples. The present invention can be applied to and is advantageous for numerous other geometries, too.

Referring to FIG. 2, first conductors 22 are formed on the surface 12 of the substrate 10. In this example, the first conductor 22 are bit lines made from tungsten (W) and are oriented perpendicular to the plane of the cross section displayed in the Figures.

Insulating material bars 24 are arranged over the first conductors 22. Preferably, the insulating material bars 24 are used as a mask for the lateral structuring of the first conductors 22. The insulating material bars 24 are made of Si₃N₄ or any other electrically insulating material. Alternatively, electrically conductive bars are provided instead of the insulating material bars 24. According to a further alternative any mask used for defining the lateral shape of the first conductors 22 is removed after the structuring and before the subsequent processing steps.

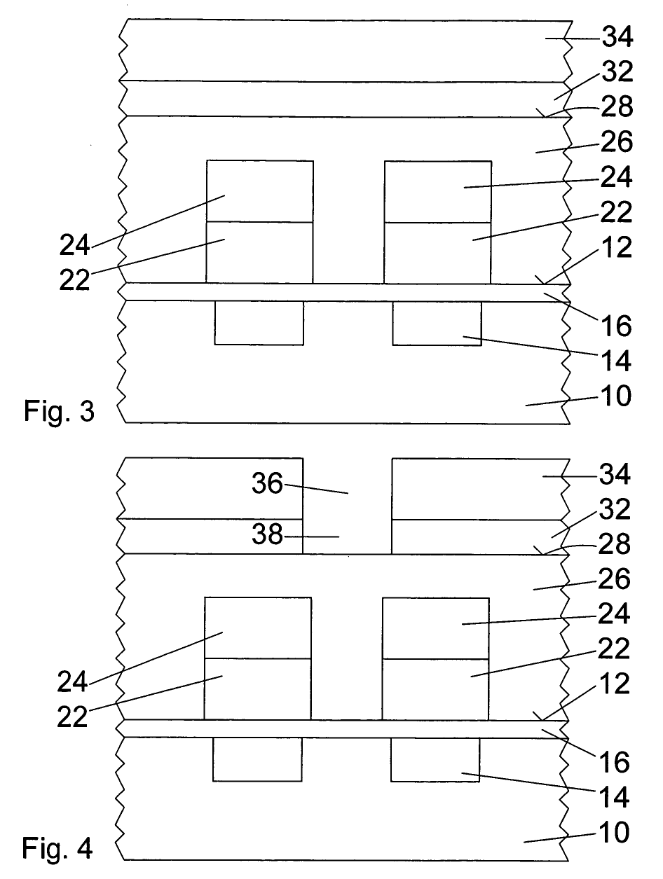

Referring to FIG. 3, the whole surface 12 of the substrate 10 and the first conductors 22 and the insulating material bars 24 are covered with an oxide 26 or any other electrically insulating material particularly insulating the first conductors 22 from each other. A planar surface 28 of the oxide 26 is produced by chemical mechanical polishing (CMP) or by other means. A polysilicon layer 32 and a photo resist layer 34 are deposited over the planar surface 28 of the oxide 26.

Referring to FIG. 4, the photo resist layer 34 is exposed by means of a lithography mask and an imaging system. The exposed photo resist layer 34 is developed thereby producing an opening 36. This lateral structure of the photo resist layer 34 is then transferred to the polysilicon layer 32 thereby producing an opening 38 in the polysilicon layer 32. It is obvious that instead of photolithography any other method may be used for the lateral structuring of the polysilicon layer 32 as well.

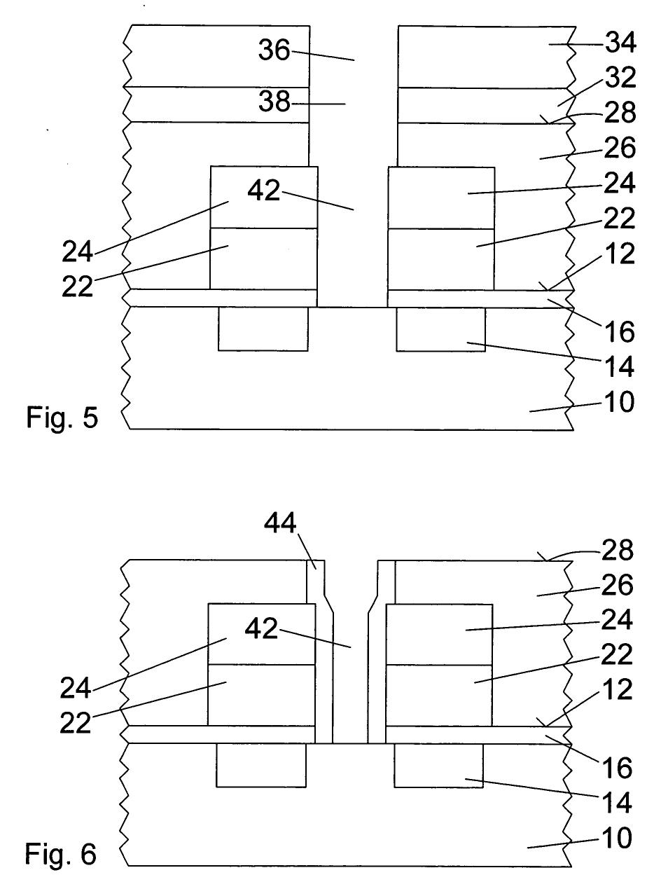

Referring to FIG. 5, by means of an anisotropic etching process the lateral structure of the photo resist layer 34 and the polysilicon layer 32 is transferred to the oxide 26 and the oxide layer 16 thereby producing the through hole 42. The anisotropic etching process does not or essentially not wear the material of the insulating material bar 24. Therefore, the lateral position and extension of the through hole 42 is self-aligned with the first conductors 22 and the insulating material bars 24 in the lateral direction parallel to the plane of the cross section displayed in the Figures.

Referring to FIG. 6, the sidewall of the through hole 42 is coated or lined with a sacrifice structure 44. Due to the shape of the through hole 42, the sacrifice structure 44 is tube shaped. Preferably, the sacrifice structure 44 is produced by an isotropic deposition process and an anisotropic etching process removing material of the sacrifice structure 44 covering the substrate 10. Before or after the deposition of the sacrifice structure material and the anisotropic etching process the photo resist layer 34 and the polysilicon layer 32 are removed.

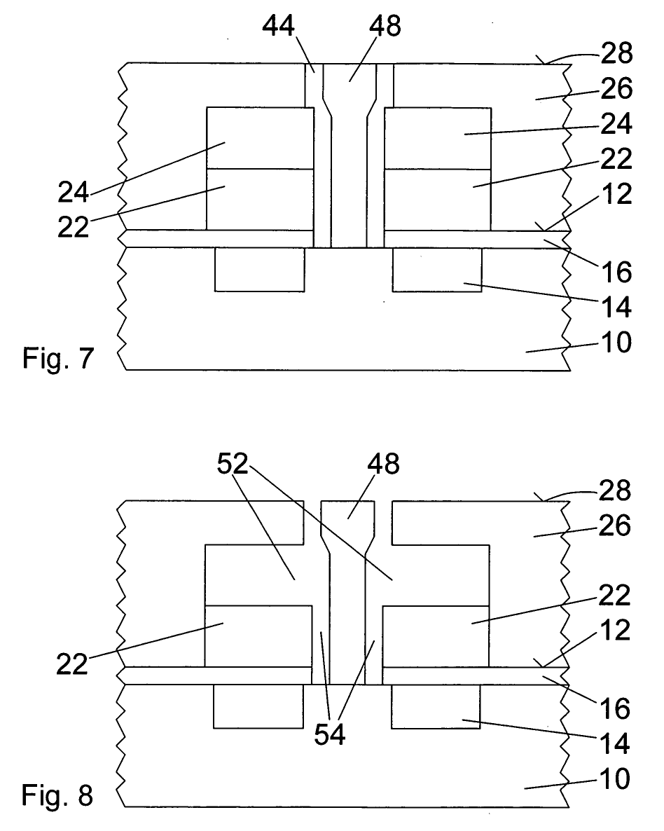

Referring to FIG. 7, the through hole 42 is filled with an electrically conductive material thereby forming a via, or via contact 48. Preferably, the via contact 48 is made of doped or highly doped polysilicon which is deposited in the through hole 42 and on the surface 28 of the oxide 26. The electrically conductive material on the surface 28 is subsequently removed by CMP.

Alternatively, the sacrifice structure 44 is produced and the electrically conductive material of the via contact 48 is deposited before the polysilicon layer 32 is removed.

Referring to FIG. 8, the sacrifice structure 44 and the insulating material bars 24 are removed thereby generating a void 52. Alternatively, merely the sacrifice structure 44 is removed. In both cases the void in place of the sacrifice structure extends to the space between the first conductors 22 and the second conductor, or via 48. In other words a gap 54 is produced between the first and second conductors 22, 48.

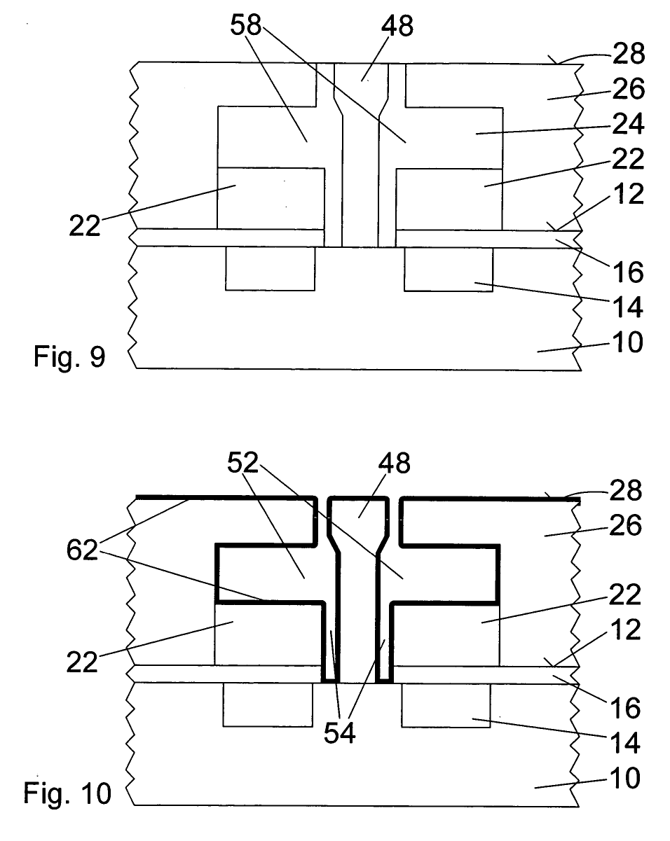

In the state displayed in FIG. 8, the void 52 and particularly the gap 54 are filled with air or any other gas the permittivity of which is very close to the vacuum permittivity and the dielectric constant of which is very close to 1. Therefore, a minimum capacitance and a minimum capacitive coupling between the first conductors 22 and the second conductor, or via contact, 48 are achieved. However, for many applications it is advantageous to further process the semiconductor device as illustrated below with reference to FIG. 9 or with reference to FIGS. 10 to 12.

Referring to FIG. 9, the void 52 and particularly the gap 54 are filled with a low k material 58 which is a dielectric material with comparatively low dielectric constant, or k factor. An oxide doped with carbon (C) and several spin on glasses with k factors of 3.0, 2.5, 2.0 and down to 1.3 are examples for the low k material 58.

An alternative is described with reference to FIGS. 10 to 12. Referring to FIG. 10, the walls of the void 52 and particularly the walls of the gap 54 are coated with an electrically insulated film 62 reducing the risk of an electrical break down between the first conductors 22 and the second conductor 48 particularly in the very small gap 54.

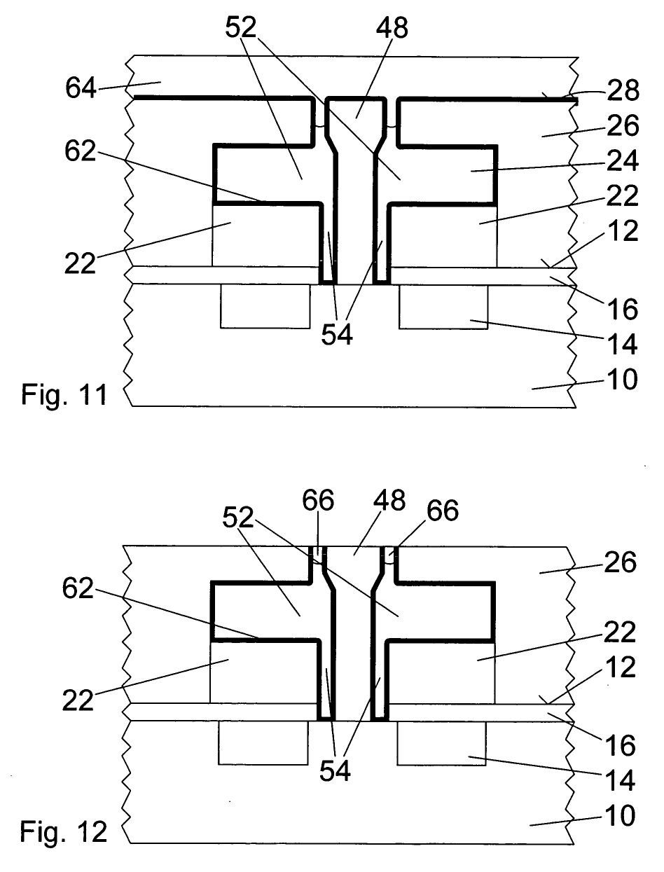

Referring to FIG. 11, the surface 28 of the oxide 26 is coated with a material 64 partially intruding into the upper part of the void 52. Referring to FIG. 12, by means of CMP or by a similar measure most of the material 64 is removed. Merely material intruded into the upper part of the void 52 remains and forms an annular sealing plug 66 sealing the void 52 from the environment.

The alternative embodiment illustrated with reference to FIGS. 10 to 12 utilizes the minimum k factor of air or another gas filling the void 52 and simultaneously provides a low risk of electrical break down in the gap 54 by means of the electrically insulating film 62.

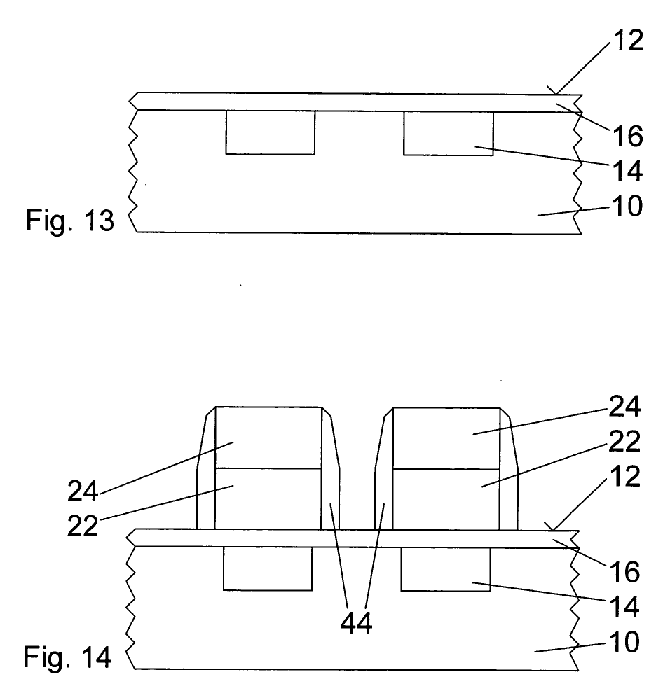

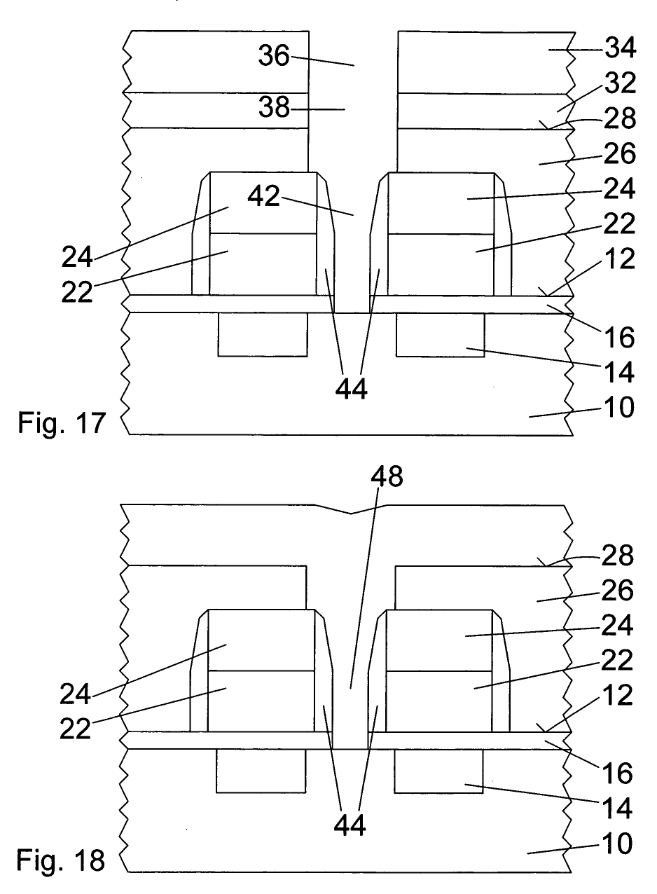

An alternative embodiment of the present invention is now described with reference to FIGS. 13 through 21. Referring to FIGS. 13 through 17, essentially the same processing steps are performed as in the embodiment described above with reference to FIGS. 1 to 5. However, the embodiment differs from the above embodiment in that spacers 44 at the sidewalls of the first conductors 22 and of the insulating materials bars 24 are provided as sacrifice structures. The spacers 44 are produced immediately after the deposition and lateral structuring of the first conductors 22 and the insulating material bars 24 by an isotropic deposition of the sacrifice structure material and an anisotropic etching process removing the sacrifice structure material on horizontal surfaces. As can be seen from FIG. 17, the through hole 42 is now self-aligned with respect to the spacers 42.

Referring to FIG. 18, an electrically conductive material is deposited in the through hole 42 and on the surface 28 of the oxide 26 after the photo resist layer 34 and the polysilicon layer 32 have been removed. Thereby, the via contact 48 is formed.

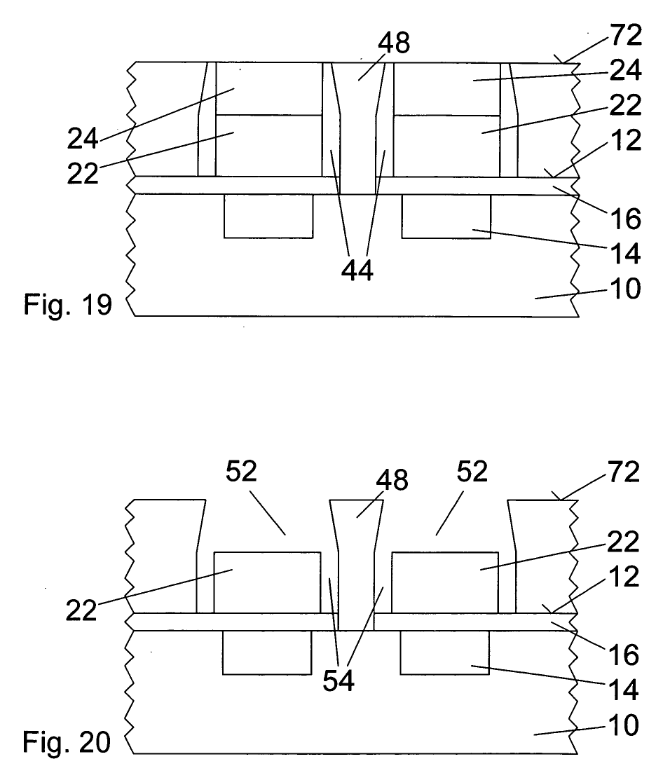

Referring to FIG. 19, the electrically conductive material of the via contact 48, the oxide 26 and optionally parts of the insulating material bars 24 and of the spacers 44 are ablated by CMP or any other suitable method. Thereby, the plane surface 72 is formed.

Referring to FIG. 20, the spacers 44 and the insulating material bars 24 are removed thereby generating a void 52 in place of the spacers 44 and in place of the insulating material bars 24. The void 52 particularly includes gaps 54 between the first conductors 22 and the second conductor 48. Alternatively, merely the spacers 44 are removed.

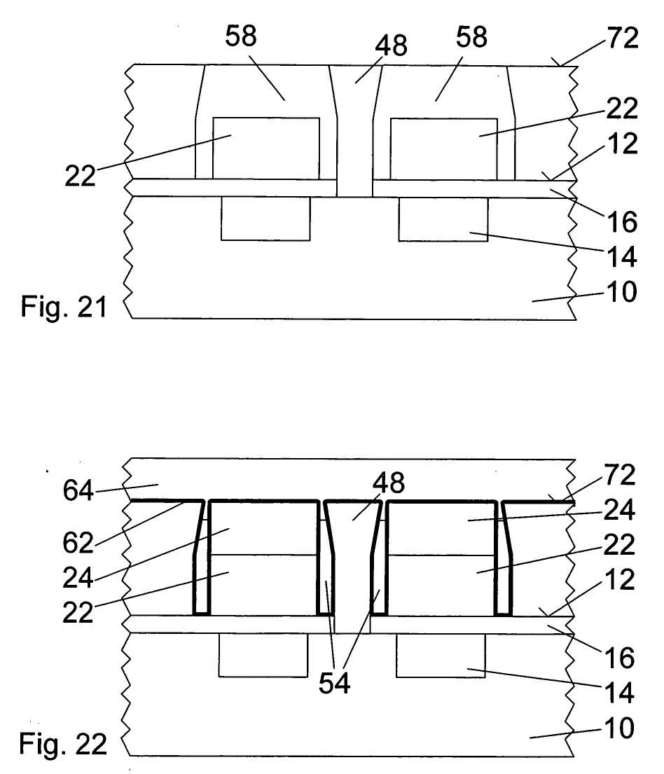

As already described above with reference to FIG. 8, due to the minimum k factor of air or any other gas filling the void 52 and particularly the gaps 54 between the first and second conductors 22 and 48, the configuration displayed in FIG. 20 provides a minimum electrostatic capacitance and hence a minimum capacitive coupling between the first and second conductors 22 and 48. However, for many applications it is advantageous to further process the structures as will be described below with reference to FIG. 21 or FIGS. 22 and 23 or FIGS. 24 to 26.

Referring to FIG. 21, the voids 52 and particularly the gaps 54 are filled with a low k material 58 as described above with reference to FIG. 9.

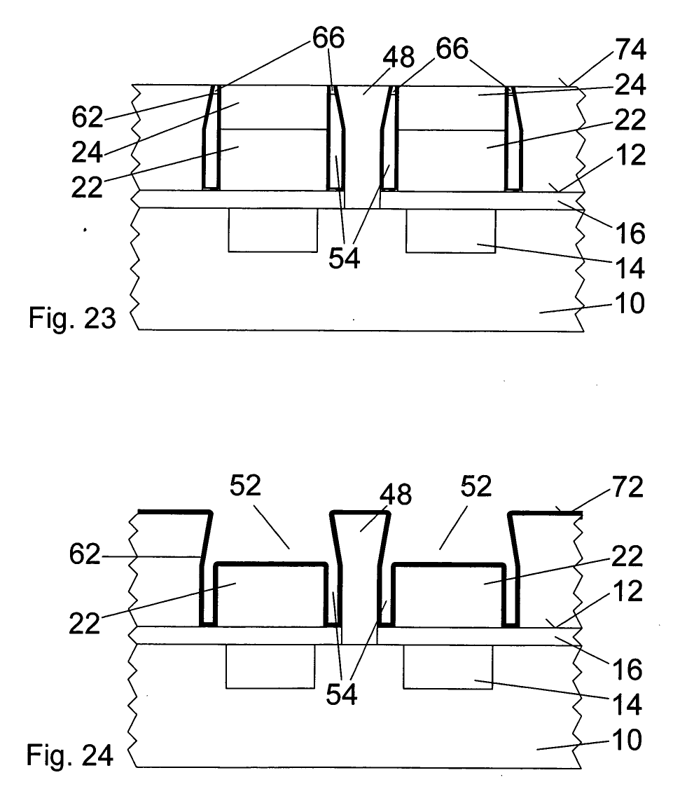

Referring to FIGS. 22 and 23, an embodiment is described in which merely the spacers 44 are removed thereby generating voids the most important parts of which are the gaps 54 between the first and second conductors 22, 48.

Referring to FIG. 22, an electrically insulating film 62 is deposited on the plane surface 72 produced as described above with reference to FIG. 19 and on the walls of the gaps 54. This electrically insulating film 62 is produced in a similar way as described above with reference to FIG. 10. Subsequently a material 64 is deposited over the plane surface 72. Similar to the above description with reference to FIG. 11, the material 64 partially intrudes into the voids or gaps 54.

Referring to FIG. 23, those parts of the material 64 over the plane surface 72 and those parts of the electrically insulating film 62 on the plane surface 72 are removed and a new plane surface 74 is produced by CMP. Only those parts of the material 64 intruded into the upper parts of the voids 52 remain and now form sealing plugs 66.

According to a further embodiment of the present invention described below with reference to FIGS. 24 to 26, both the spacers 44 and the insulating material bars 24 are removed after the plane surface 72 has been produced as described above with reference to FIGS. 19 and 20.

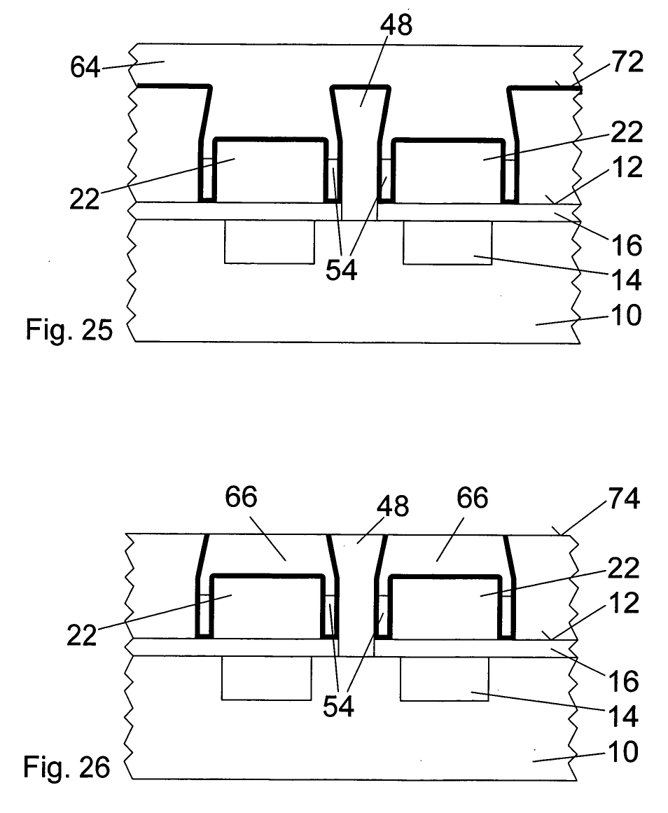

Referring to FIG. 24, the plane surface 72, the walls of the voids 52 and in particular the walls of the gaps 54 are coated with an electrically insulating film 62. Referring to FIG. 25, a material 64 is deposited over the plane surface 72 and in the upper bigger parts of the voids 52. The material 64 further partially intrudes into the upper parts of the gaps 54 between the first and second conductors 22, 48. Preferably the material 64 is a low k material since it partially fills the narrow gaps 54 between the first and second conductors 22, 48.

Referring to FIG. 26, the material 64 above the plane surface 72 and those parts of the electrically insulating films 62 deposited on the plane surface 72 are removed by CMP or any other suitable method as described above with reference to FIGS. 12 and 23. The material 64 remains in the upper parts of the voids 52 including the upper parts of the gaps 54, thereby forming sealing plugs 66 sealing the gaps 54 from the environment. It is obvious that the capacitance between the first and second conductors 22, 48 depends on the extent to which the material 64 intrudes into the gaps 54. Therefore, according to a preferred alternative, the material 64 merely fills the upper parts of the voids 52 but does not intrude into the gaps 54.

It is noted that the geometry of the sacrifice structures 44 in the embodiments described above with reference to FIGS. 1 to 12 is completely different from the geometry of the sacrifice structure 44 of the embodiments described above with reference to FIGS. 13 through 26. Since the sacrifice structure 44 is replaced by air or a low k material, the same difference exists for the geometries of the finally air filled voids 52 and/or gaps 54, or for the geometry of the low k material 58, respectively.

In the embodiments described above with reference to FIGS. 1 to 12 the sacrifice structure is tube shaped and laterally encloses the second conductor, or via contact 48. In the embodiments described above with reference to FIGS. 13 to 26, the sacrifice structure 44 is formed by spacers coating the side walls of the first conductors 22.

In both geometries there are embodiments in which the insulating material bars 24 are removed, too. In these cases the insulating material bars 24 are also sacrifice structures. It is to be further noted that in the embodiments described above with reference to FIGS. 1 to 12 the insulating material bars 24 are not necessarily removed completely as displayed in FIG. 9. Rather, it is sufficient to remove the insulating material bars 24 in the vicinity of the second conductor, or via contact 48.

If both the primary sacrifice structure 44 and the insulating material bars 24 are to be removed both are preferably made of the same material or an etching process is used which removes both the materials of the primary sacrifice structure 44 and the insulating material bars 24.

If the integrated semiconductor device is a memory device and also in other cases it may be advantageous to protect parts of the device by a block mask when the sacrifice structure 44 is removed. In this case structures made of the same material but protected by the block mask are not removed. For example it is particularly advantageous to protect the support area of a memory device by a block mask.

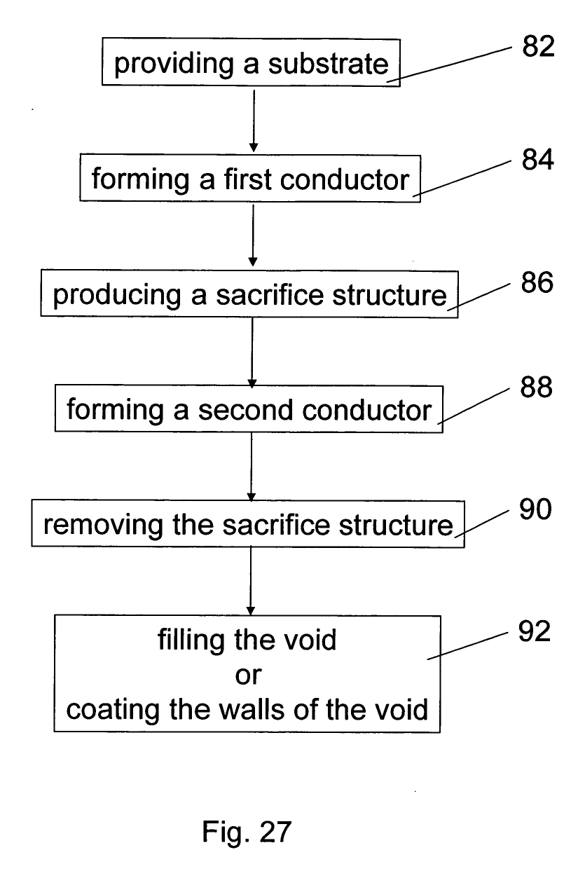

FIG. 27 is a schematic flow chart of a method according to the present invention. In a first step 82 a semiconductor substrate 10 with a surface 12 is provided. In a second step 84 a conductive member, or first conductor 22 is formed on the surface 12 of the substrate 10. According to the embodiments described above, the conductive member 22 is provided for conducting a current in a direction parallel to the surface 12 of the substrate 10.

In a third step 86 a sacrifice structure 44 is provided. In a fourth step 88 a second conductor is formed. According to the embodiments described above this second conductor 48 is a via contact provided for conducting a current in a direction vertical to the surface 12 of the substrate 10. Preferably the sacrifice structure 44 at least partially defines the shape and position of the second conductor 48. The first conductor 22 and the second conductor 48 are separated from each other by the sacrifice structure.

The second through fourth steps 84, 86, 88 may be performed in a different order, too. According to a preferred alternative, the sacrifice structure is produced before both the first and second conductors 22, 48 are formed. This alternative is particularly advantageous when the sacrifice structure defines the shape and position of both the first and second conductors.

In a fifth step 90 the sacrifice structure is removed thereby generating a void in place of the sacrifice structure 44. In an optional sixth step 92 the void 52 is filled with a low k material 58 or the walls of the void 52 are coated with an electrically insulating film 62.

It is obvious that the embodiments described above may be easily modified in numerous aspects without departing from the scope of the present invention. Therefore, the embodiments described above with reference to the Figures are merely given for the purpose of illustration. The present invention and the scope of protection sought by the present application are solely defined by the appended claims.

What is claimed is:

1. A method for manufacturing an integrated semiconductor memory device with low capacitive coupling between a conductive member and a via, comprising:
providing a semiconductor substrate with a surface;
forming the conductive member on the surface of the substrate, the conductive member provided for conducting a current in a direction parallel to the surface of the substrate;
producing a sacrifice structure;
forming the via, the via provided for conducting a current in a direction vertical to the surface of the substrate, wherein the sacrifice structure at least partially defines a shape and position of the via, and wherein the sacrifice structure separates the conductive member and the via; and
removing the sacrifice structure, thereby generating a void in place of the sacrifice structure.

2. The method according to claim 1, wherein the conductive member is a bit line and the via is provided for connecting a storage capacitor and a transistor.

3. The method according to claim 1, wherein
an insulating material is deposited on the surface of the substrate and covering the conductive member;
a through hole is produced in the insulating material;
the sacrifice structure is produced with a tube shape lining the sidewall of the through hole; and the via is formed in the through hole, the sacrifice structure laterally enclosing the via.

4. The method according to claim 1, wherein
the sacrifice structure is produced as a spacer lining at least one sidewall of the conductive member;
an insulating material is deposited on the surface of the substrate adjacent to the sacrifice structure;
a through hole adjacent to the sacrifice structure is produced in the insulating material; and
the via is formed in the through hole, the sacrifice structure separating the via from the conductive member.

5. The method according to claim 1, further comprising:
at least partially filling the void with a dielectric material.

6. The method according to claim 1, further comprising:
coating walls of the void with an electrically insulating film.

7. A method for manufacturing an integrated semiconductor device with low capacitive coupling between proximate conductors, comprising:
providing a semiconductor substrate with a surface;
producing a sacrifice structure on the surface;
forming a first conductor, wherein the first conductor is separated from a second conductor by the sacrifice structure; and
removing the sacrifice structure, thereby generating a void in place of the sacrifice structure.

8. The method according to claim 7, wherein the sacrifice structure defines a shape and position of the first conductor.

9. The method according to claim 7, further comprising:
at least partially filling the void with a dielectric material.

10. The method according to claim 7, further comprising:
coating walls of the void with an electrically insulating film.

11. A method for manufacturing an integrated semiconductor device with low capacitive coupling between two proximate conductors, comprising:
providing a semiconductor substrate with a first conductor and a second conductor on a surface of the substrate and a sacrifice structure between the first conductor and the second conductor;
removing the sacrifice structure, thereby generating a void in place of the sacrifice structure.

12. The method according to claim 11, further comprising:
at least partially filling the void with a dielectric material.

13. The method according to claim 12, wherein the dielectric material is a low-k material.

14. The method according to claim 11, further comprising:
coating walls of the void with an electrically insulating film.

15. The method according to claim 14, wherein the insulating film is an oxide liner.

16. An integrated semiconductor device, comprising:
a semiconductor substrate with a surface;
a first conductor on the surface of the substrate;
a second conductor on the surface of the substrate; and
a void between the first conductor and the second conductor, wherein the void is filled with gas.

17. The integrated semiconductor device according to claim 16, wherein the void is produced by:
removing a sacrifice structure between the first conductor and the second conductor, thereby generating the void in place of the sacrifice structure.

18. The integrated semiconductor device according to claim 16, wherein the void is sealed off from the environment of the substrate.

19. The integrated semiconductor device according to claim 16, wherein walls of the void are coated with an electrically insulating film.

20. An integrated semiconductor device, comprising:
a semiconductor substrate with a surface;
a first conductor on the surface of the substrate;
a second conductor on the surface of the substrate; and
an insulating structure between the first conductor and the second conductor, wherein the insulating structure is produced by:
removing a sacrifice structure between the first conductor and the second conductor, thereby generating a void in place of the sacrifice structure, wherein a shape of the sacrifice structure is essentially equal to a shape of the insulating structure; and
filling the void with an insulating material, thereby forming the insulating structure.
